(19) United States
(12) Patent Application Publication
(10) Pub. No.: US 2007/0082503 A1
(43) Pub. Date: Apr. 12, 2007

(54) METHOD OF FABRICATING A DIELECTRIC LAYER

(76) Inventors: Yun-Ren Wang, Tainan (TW); Ying-Wei Yen, Miaoli County (TW); Chien-Hua Lung, Hsinchu County (TW); Shu-Yen Chan, Hsinchu County (TW); Kuo-Tai Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,218

(22) Filed: Oct. 11, 2005

(51) Int. Cl. H01L 21/31; H01L 21/469

(52) U.S. Cl. 438/778

(57) ABSTRACT

A method of fabricating a dielectric layer is described. A substrate is provided, and a dielectric layer is formed over the substrate. The dielectric layer is performed with a nitridation process. The dielectric layer is performed with a first annealing process. A first gas used in the first annealing process includes inert gas and oxygen. The first gas has a first partial pressure ratio of inert gas to oxygen. The dielectric layer is performed with the second annealing process. A second gas used in the second annealing includes inert gas and oxygen. The second gas has a second partial pressure ratio of inert gas to oxygen, and the second partial pressure ratio is smaller than the first partial pressure ratio. At least one annealing temperature of the two annealing processes is equal to or greater than 950° C. The invention improves uniformity of nitrogen dopants distributed in dielectric layer.

### BACKGROUND OF THE INVENTION

1 . Field of Invention

The present invention relates to the method for fabricating a film layer in a semiconductor device. More particularly, the present invention relates to a method for fabricating a dielectric layer.

2 . Description of Related Art

When the integration for semiconductor device in integrated circuit is getting larger and larger, it is also requited to have supper-thin gate dielectric layer with high dielectric constant and low leakage current. When the size of a metal oxide semiconductor (MOS) transistor is less than 100 nm, the dielectric constant usually needs to be greater than 7. The material with higher dielectric constant can improve isolation effect. However, the gate dielectric layer in MOS transistor is formed by silicon oxide, and the dielectric constant for the silicon oxide is about 3.9. The silicon oxide is therefore not suitable for use as the dielectric layer in the MOS device with more and more reduced size. The conventional technology usually uses the nitridation process to dope the dielectric layer of silicon oxide, so as to increase the dielectric constant.

The usual nitridation process includes thermal nitridation process and the plasma nitridation process. The Thermal nitridation process uses the rapid thermal nitridation to dope the nitrogen atoms into the dielectric layer. However, after the thermal nitridation process, the nitrogen dopants are not uniformly distributed in the dielectric layer.

Another nitridation process is the plasma nitridation process. The plasma nitridation process uses the method of ion bombardment to dope the nitrogen atoms into the dielectric layer. However, the plasma nitridation process would cause the nitrogen dopants to be not uniformly distributed in the dielectric layer, and further destroy the surface of the dielectric layer, resulting in the occurrence of direct-tunneling current.

### SUMMARY OF THE INVENTION

The invention provides a method for fabricating a dielectric layer, wherein the nitrogen dopants can have uniform distribution in the dielectric layer.

The present invention provides a method for fabricating a semiconductor transistor, wherein the present invention can mend the damage on the surface of the dielectric layer, due to the plasma used in the plasma nitridation process.

The invention provides a method for fabricating a dielectric layer. The method includes providing a substrate with a dielectric layer formed thereon. Then, a nitridation process is performed on the dielectric layer. A first annealing process is performed on the dielectric layer. The first annealing process uses a first gas, such as the gas having an inert gas and oxygen. The inert gas to the oxygen in the first gas has a first partial pressure ratio. Then, a second annealing process is performed on the dielectric layer. The second annealing process uses a second gas, such as the gas having an inert gas and oxygen. The inert gas to the oxygen in the second gas has a second partial pressure ratio. The second partial pressure ratio is smaller than the first partial pressure ratio.

According to an embodiment of the invention, in the foregoing method for fabricating a dielectric layer, the inert gas includes, for example, nitrogen or noble gas.

According to an embodiment of the invention, in the foregoing method for fabricating a dielectric layer, the noble gas includes, for example, helium, neon, argon, krypton, xenon, or radon.

According to an embodiment of the invention, in the foregoing method for fabricating a dielectric layer, the nitridation process includes, for example, a thermal nitridation process or a plasma nitridation process.

According to an embodiment of the invention, in the foregoing method for fabricating a dielectric layer, a gas used in the nitridation process includes, for example, a nitrogen-containing gas.

According to an embodiment of the invention, in the foregoing method for fabricating a dielectric layer, the nitrogen-containing gas includes, for example, N, NO or N0₂.

According to an embodiment of the invention, in the foregoing method for fabricating a dielectric layer, at least one of the first annealing process and the second annealing process is performed under a temperature range of equal to or greater than 950° C.

According to an embodiment of the invention, in the foregoing method for fabricating a dielectric layer, the dielectric layer is formed by, for example, thermal oxidation.

According to an embodiment of the invention, in the foregoing method for fabricating a dielectric layer, the dielectric layer includes, for example, a gate dielectric layer.

According to an embodiment of the invention, in the foregoing method for fabricating a dielectric layer, a material for the dielectric layer includes, for example, silicon oxide.

The invention provides a method for fabricating a dielectric layer. The method includes providing a substrate with a dielectric layer formed thereon. Then, a nitridation process is performed on the dielectric layer. A first annealing process is performed on the dielectric layer. The first annealing process uses a first gas, such as the gas having an inert gas and oxygen. The inert gas to the oxygen in the first gas has a first partial pressure ratio. Then, a second annealing process is performed on the dielectric layer. The second annealing process uses a second gas, such as the gas having an inert gas and oxygen. The inert gas to the oxygen in the second gas has a second partial pressure ratio. The second partial pressure ratio is smaller than the first partial pressure ratio. Then, a third annealing process is performed on the dielectric layer. The third annealing process uses a third gas, such as the gas having an inert gas and oxygen. The inert gas to the oxygen in the third gas has a third partial pressure ratio. The third partial pressure ratio is larger than the second partial pressure ratio.

According to an embodiment of the invention, in the foregoing method for fabricating a dielectric layer, the inert gas includes, for example, nitrogen or noble gas.

According to an embodiment of the invention, in the foregoing method for fabricating a dielectric layer, the nitridation process includes, for example, a thermal nitridation process or a plasma nitridation process.

According to an embodiment of the invention, in the foregoing method for fabricating a dielectric layer, a gas used in the nitridation process includes, for example, a nitrogen-containing gas.

According to an embodiment of the invention, in the foregoing method for fabricating a dielectric layer, at least one of the first annealing process, the second annealing process, and the third annealing process is performed under a temperature range of equal to or greater than 950° C.

According to an embodiment of the invention, in the foregoing method for fabricating a dielectric layer, the dielectric layer includes, for example, a gate dielectric layer.

The invention provides a method for fabricating a dielectric layer. The method includes providing a substrate with a dielectric layer formed thereon. Then, a nitridation process is performed on the dielectric layer. A first annealing process is performed on the dielectric layer. The first annealing process uses a first gas, such as the gas having an inert gas. Then, a second annealing process is performed on the dielectric layer. The second annealing process uses a gas, such as the mixed gas having an inert gas and oxygen.

According to an embodiment of the invention, in the foregoing method for fabricating a dielectric layer, after performing the second annealing process on the dielectric layer, the method further includes performing a third annealing process on the dielectric layer. The gas being used includes, for example, the inert gas.

According to an embodiment of the invention, in the foregoing method for fabricating a dielectric layer, at least one of the first annealing process, the second annealing process, and the third annealing process is performed under a temperature range of equal to or greater greater than 950° C.

According to an embodiment of the invention, in the foregoing method for fabricating a dielectric layer, at least one of the first annealing process and the second annealing process is performed under a temperature range of equal to or greater than 950° C.

According to an embodiment of the invention, in the foregoing method for fabricating a dielectric layer, the inert gas includes, for example, nitrogen gas or noble gas.

According to an embodiment of the invention, in the foregoing method for fabricating a dielectric layer, the dielectric layer includes, for example, gate dielectric layer.

The invention performs at least two annealing processes on he dielectric layer after performing the nitridation process on the dielectric layer. Therefore, the nitrogen dopants distributed in the dielectric layer can be uniform due to changing the partial pressure ratio of the inert gas to the oxygen.

In addition, since at least one of the annealing processes is performed under the temperature range of equal to or greater than 950° C., it can mend the dielectric surface, which is destroyed by the plasma during the plasma nitridation process.

In another hand, when the dielectric layer formed in the invention is a gate dielectric layer, the electric performance of the MOS transistor can be improved, including improvements of the equivalent oxide thickness (EOT) and threshold voltage, and so on.

In addition, the invention can extend the application in the process with line width by 90/65 nm, so as to improve the capability of deposition dielectric layer and plasma nitridation process. Further, since the invention can be easily performed, it can be integrated with the current fabrication process, so as to achieve the massive production.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is drawing, schematically illustrating the process flow for fabricating a dielectric layer, according to an embodiment of the invention.

FIG. 2 is cross-sectional view, schematically illustrating the process flow for fabricating a dielectric layer, according to an embodiment of the invention.

FIG. 3A-FIG. 3B are cross-sectional views, schematically illustrating the process flow for fabricating a MOS transistor, according to an embodiment of the invention.

### DESCRIPTION OF THE PREFERRED EMBODIMENTS

The invention performs at least two annealing processes on he dielectric layer after performing the nitridation process on the dielectric layer. The nitrogen dopants distributed in the dielectric layer can be uniform when the partial pressure ratio of the inert gas to the oxygen satisfies the following condition.

At a situation for performing the second annealing process, the first partial pressure ratio (inert gas/oxygen gas) ₁for the inert gas to the oxygen gas in the first annealing process is greater than the second partial pressure ratio (inert gas/oxygen gas)₂for the inert gas to the oxygen gas in the second annealing process, as follows: (inert gas/oxygen gas)₁>(inert gas/oxygen gas) ₂.

At a situation for performing the third annealing process, the first partial pressure ratio (inert gas/oxygen gas) ₁for the inert gas to the oxygen gas in the first annealing process is greater than the second partial pressure ratio (inert gas/oxygen gas) ₂for the inert gas to the oxygen gas in the second annealing process. The second partial pressure ratio (inert gas/oxygen gas) ₂is less than the third partial pressure ratio (inert gas/oxygen gas) ₃for the inert gas to the oxygen gas in the third annealing process, as follows: (inert gas/oxygen gas) ₁>(inert gas/oxygen gas) ₂. (inert gas/oxygen gas) ₂<(inert gas/oxygen gas) _{3.}

In the foregoing mathematic relations, the first annealing process and the third annealing process can include the specific condition for only using the inert gas. That is, quantities of (inert gas/oxygen gas) ₁and the (inert gas/oxygen gas) ₃can be infinity.

In the following descriptions, the embodiments are used for describing the method of the invention for fabricating the dielectric layer.

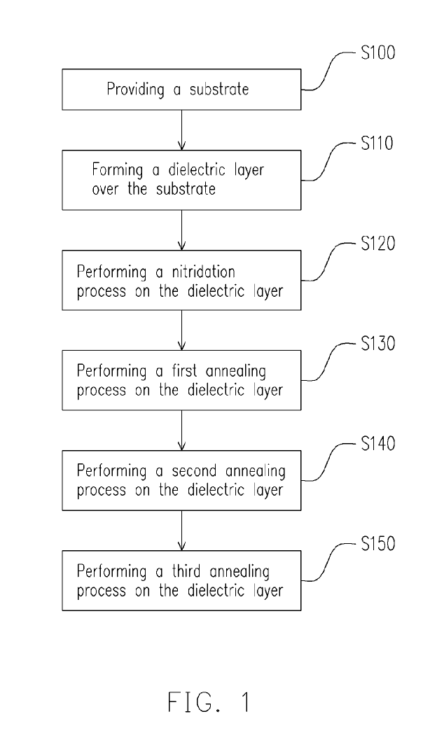

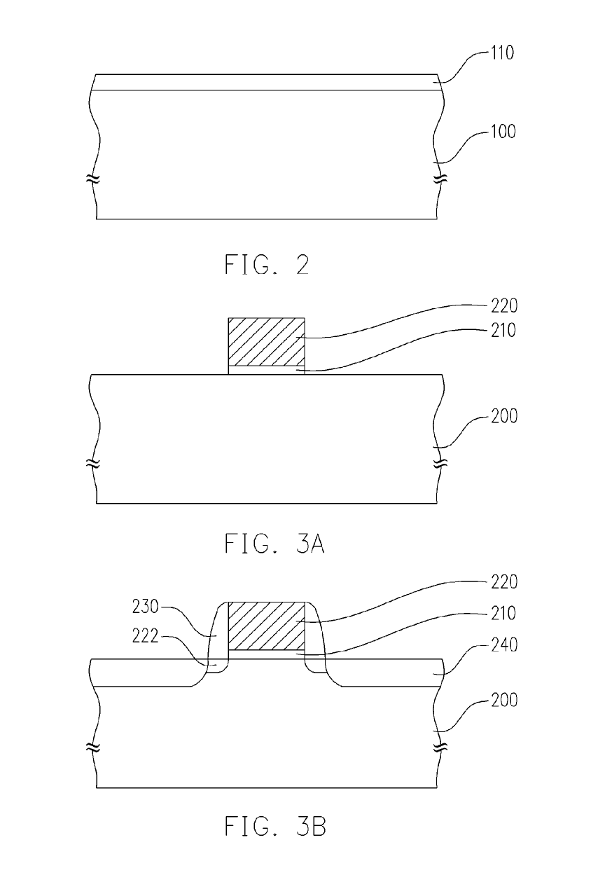

FIG. 1 is drawing, schematically illustrating the process flow for fabricating a dielectric layer, according to an embodiment of the invention. FIG. 2 is a cross-sectional view, schematically illustrating the process flow for fabricating a dielectric layer, according to an embodiment of the invention.

Referring to FIG. 1 and FIG. 2, a substrate 100 is first provided, in step SI 00. The substrate 100 can be, for example, a silicon substrate, or preferably a doped monocrystalline silicon substrate.

Then, in step S110, a dielectric layer 110 is formed on the substrate 100. The dielectric layer includes, for example, a gate dielectric layer, and the material for the dielectric layer 110 includes, for example, silicon oxide. The process for forming the dielectric layer 110 includes, for example, the thermal oxidation or the chemical vapor deposition.

Then, a nitridation process is performed on the dielectric layer 110, in step S120. The nitridation process being performed includes, for example, the thermal nitridation or plasma nitridation. The gas used in the nitridation process includes, for example, nitrogen-containing gas, such as N, NO or N0₂.

Then, a first annealing process, in step S130, is performed on the dielectric layer 110. The gas used in the first annealing process S130 includes, for example, a first gas having inert gas with oxygen. The inert gas includes, for example, nitrogen or noble gas. The noble gas can be helium, neon, argon, krypton, xenon, or radon. The inert gas to the oxygen gas has a first partial pressure ratio, such as 9:1.

A second annealing process, in step S140, is performed on the dielectric layer 110. The gas used in the second annealing process S140 includes, for example, a second gas having inert gas with oxygen. The inert gas includes, for example, nitrogen or noble gas. The noble gas can be helium, neon, argon, krypton, xenon, or radon. The inert gas to the oxygen gas has a second partial pressure ratio. The second partial pressure ratio is less than the first partial pressure ratio. The second partial pressure ratio includes, for example, 9:2.

In addition, a third annealing process, in step S150, can be further performed on the dielectric layer 110. The gas used in the third annealing process includes, for example, a third gas having inert gas with oxygen. The inert gas includes, for example, nitrogen or noble gas. The noble gas can be helium, neon, argon, krypton, xenon, or radon. The inert gas to the oxygen gas has a third partial pressure ratio. The third partial pressure ratio is greater than the second partial pressure ratio. The third partial pressure ratio is, for example, 9:1.

In addition, if two annealing processes are performed, then at least one the two annealing processes is under a temperature range of equal to or greater than 95020 C. If three annealing processes are performed, then at least one the three annealing processes is under a temperature range of equal to or greater than 95020 C.

In another embodiment, in step S130, during performing the first annealing process on the dielectric layer 110, the first gas being used includes, for example, the inert gas, such as nitrogen gas or noble gas. In step 140, during performing the second annealing process on the dielectric layer 110, the second gas being used includes, for example, a mixed gas of inert gas with oxygen. The second partial pressure ratio is, for example, 9:1. Likewise, in step S150, during performing the third annealing process on the dielectric layer 110, the third gas being used is, for example, the inert gas, such as nitrogen or noble gas.

Since the invention performs at least twice of annealing processes on the dielectric layer 110, the nitrogen dopants can be uniformly distributed in the dielectric layer 110 by changing the partial pressure ratio of the inert gas to the oxygen gas. The present invention is a convenient and low-cost treatment. In addition, during performing these annealing processes, at least one of the annealing processes is under an environment at temperature range of equal to or greater than 950° C, so as to mend the damaged surface of the dielectric 110 due to the plasma nitridation process.

FIG. 3A-FIG. 3B are cross-sectional views, schematically illustrating the process flow for fabricating a MOS transistor, according to an embodiment of the invention.

Referring to FIG. 3A, a substrate 200 is provided. The substrate 200 can be, for example, a silicon substrate, or preferably a doped monocrystalline silicon substrate.

Then, a dielectric layer 210 is formed on the substrate 200. The dielectric layer 210 is, for example, a gate dielectric layer, and the material for the dielectric layer 210 is, for example, silicon oxide. The process for forming the dielectric layer 210 is, for example, the thermal oxidation or the chemical vapor deposition.

After then, a nitridation process is performed on the dielectric layer 210. The nitridation process is, for example, a plasma nitridation process. The gas used in the plasma nitridation process includes, for example, nitrogen-containing gas. The nitrogen-containing gas includes, for example, N, NO, or N0_{2.}

Then, a first annealing process is performed on the dielectric layer 210. The gas used in the first annealing process includes, for example, a first gas having inert gas with oxygen gas. The inert gas includes, for example, nitrogen or noble gas. The noble gas can be helium, neon, argon, krypton, xenon, or radon. The inert gas to the oxygen gas in the first gas has a first partial pressure ratio, such as 9:1.

Then, a second annealing process is performed on the dielectric layer 210. The gas used in the second annealing process is, for example, a second gas having inert gas with oxygen gas. The inert gas includes, for example, nitrogen or noble gas. The noble gas can be helium, neon, argon, krypton, xenon, or radon. The inert gas to the oxygen gas in the second gas has a second partial pressure ratio. The second partial pressure ratio is less than the first partial pressure ratio, such as 9:2.

In addition, at least one of the two annealing processes is performed under a temperature range of greater than 95020 C.

In the foregoing steps, the person with ordinary skill in the art can adjust the foregoing processes according to the actual fabrication condition. For example, the number of annealing processes being performed or the gas being used can be changed. Here, the additional descriptions are omitted.

Then, a gate electrode 220 is formed on the dielectric layer 210. Wherein, the gate electrode 220 is doped polysilicon. The method for forming the gate electrode 220 includes, for example, performing a chemical vapor deposition process with insitu doping, so as to form a doped polysilicon material layer (not shown), and then patterning the doped polysilicon material layer. In the etching process for forming the formed gate electrode 220, the gate dielectric layer 210 can also be patterned, and a portion of the gate dielectric layer 210 under the gate electrode 220 remains. As a result, the substrate 200 is then exposed.

Referring to FIG. 3B, a source/drain extension region 222 is formed in the substrate 200 at both sides of the gate electrode 220. The source/drain extension region 222 is formed, for example, by using the gate electrode 220 as the mask and performing an ion implantation process.

A spacer 230 is formed on the sidewall of the gate electrode 220. The spacer 230 is for example, silicon nitride. The method for forming spacer includes, for example, forming a silicon nitride material layer (not shown) over the substrate 200, and performing an etching back process on the silicon nitride material layer.

Then, a source/drain region 240 is formed in the substrate 200 at both sides of the gate electrode 220. The method for forming the source/drain region 240 includes, for example, using the spacer 230 and the gate electrode 220 as the mask, and performing an ion implantation process on the substrate 200.

Since the gate dielectric layer 210, which is formed by the method of the invention, has the relatively larger dielectric constant, the electrical performance of the MOS transistor can be improved, including the improvements of equivalent oxide thickness and the threshold voltage.

In addition, the method of the present invention can be applied to the fabrication process with line width of 90/65 nm, so as to improve the capability of deposition dielectric layer and plasma nitridation process. Further, since the invention can be easily performed, it can be integrated with the current fabrication process, so as to achieve the massive production.

In accordance with the foregoing descriptions, the invention at least has the advantages as follows.

1 . The nitridation process in the invention can improve the dielectric constant of the silicon oxide and improve the isolation effect of the dielectric layer.

2 . The invention performs at least twice of twice of annealing processes on the dielectric layer after performing the nitridation process, the nitrogen dopants can be uniformly distributed in the dielectric layer by changing the partial pressure ratio of the inert gas to the oxygen gas.

3 . At least one of the annealing processes is under an environment at temperature range of equal to or greater than 950° C, so as to mend the damaged surface of the dielectric 110 due to the plasma nitridation process.

4 . The formation of the dielectric layer as the gate dielectric layer in the invention can improve the electrical performance of the MOS transistor, including the improvements of equivalent oxide thickness and the threshold voltage.

5 . The invention can be further applied to the fabrication process by line width of 90/65 nm, so as to increase capability of the deposition of dielectric layer and the plasma nitridation process. Also and, since the invention can be easily performed, it can be integrated with the current fabrication process, so as to achieve the massive production.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method of fabricating dielectric layer, comprising:
providing a substrate;
forming a dielectric layer over the substrate;
performing a nitridation process on the dielectric layer;
performing a first annealing process on the dielectric layer, wherein a first gas including an inert gas and an oxygen gas is used, and the inert gas to the oxygen gas in the first gas has a first partial pressure ratio; and
performing a second annealing process on the dielectric layer, wherein a second gas including the inert gas and the oxygen gas is used, and the inert gas to the oxygen gas in the second has a second partial pressure ratio, and the second partial pressure ratio is less than the first partial pressure ratio.

2. The method of claim 1, wherein the inert gas is a nitrogen gas or a noble gas.

3. The method of claim 2, wherein the noble gas comprises helium, neon, argon, krypton, xenon, or radon.

4. The method of claim 1, wherein the nitridation process comprises a thermal nitridation process or a plasma nitridation process.

5. The method of claim 1, wherein the nitridation process uses a nitrogen-containing gas.

6. The method of claim 5, wherein the nitrogen-containing gas comprises N, NO, or N0₂.

7. The method of claim 1, wherein at least one of the first annealing process and the second annealing process is performed under a temperature range of equal to or greater than 950° C.

8. The method of claim 1, wherein the step of forming the dielectric layer comprises a thermal oxidation.

9. The method of claim 1, wherein the dielectric layer comprises dielectric layer.

10. The method of claim 1, wherein a material of the dielectric layer comprises silicon oxide.

11. A method of fabricating dielectric layer, comprising:
providing a substrate;
forming a dielectric layer over the substrate;
performing a nitridation process on the dielectric layer;
performing a first annealing process on the dielectric layer, wherein a first gas including an inert gas and an oxygen gas is used, and the inert gas to the oxygen gas in he first gas has a first partial pressure ratio;
performing a second annealing process on the dielectric layer, wherein a second gas including the inert gas and the oxygen gas is used, and the inert gas to the oxygen gas in the second gas has a second partial pressure ratio, and the second partial pressure ratio is less than the first partial pressure ratio; and
performing a third annealing process on the dielectric layer, wherein a third gas including the inert gas and the oxygen gas is used, and the inert gas to the oxygen gas in the third gas has a second partial pressure ratio, and the third partial pressure ratio is greater than the second partial pressure ratio.

12. The method of claim 11, wherein the inert gas comprises a nitrogen gas or a noble gas.

13. The method of claim 11, wherein the nitridation process comprises a thermal nitridation process or a plasma nitridation process.

14. The method of claim 11, wherein the nitridation process uses a nitrogen-containing gas.

15. The method of claim 11, wherein at least one of the first annealing process, the second annealing process, and the third annealing process is performed under a temperature range of equal to or greater than 950° C.

16. The method of claim 11, wherein the dielectric layer comprises a gate dielectric layer.

17. A method of fabricating dielectric layer, comprising:
providing a substrate;
forming a dielectric layer over the substrate;
performing a nitridation process on the dielectric layer;
performing a first annealing process on the dielectric layer, wherein an inert gas is used, and
performing a second annealing process on the dielectric layer, wherein a mixed gas of the inert gas and an oxygen gas is used.

18. The method of claim 17, wherein after performing the second annealing process on the dielectric layer, the method further comprises performing a third annealing process on the dielectric layer, and the inert gas is used.

19. The method of claim 18, wherein at least one of the first annealing process, the second annealing process, and the third annealing process is performed under a temperature range of equal to or greater than 950° C.

20. The method of claim 17, wherein at least one of the first annealing process and the second annealing process is performed under a temperature range of equal to or greater than 950° C.

21. The method of claim 17, wherein the inert gas is a nitrogen gas or a noble gas.

22. The method of claim 17, wherein the dielectric layer is a gate dielectric layer.
